(19) United States
(12) Patent Application Publication
(10) Pub. No.: US 2025/0318310 A1
(43) Pub. Date: Oct. 9, 2025

(54) Stacked Silicon Photomultipliers

(71) Applicant: SEMICONDUCTOR COMPONENTS INDUSTRIES, LLC, Scottsdale, AZ (US)

(72) Inventors: Vincenzo SESTA, Cork (IE); Stephen John BELLIS, Cobh (IE); Brian Patrick MCGARVEY, Templemartin (IE); Vladimir KOROBOV, San Mateo, CA (US)

(73) Assignee: SEMICONDUCTOR COMPONENTS INDUSTRIES, LLC, Scottsdale, AZ (US)

(21) Appl. No.: 18/762,934

(22) Filed: Jul. 3, 2024

Related U.S. Application Data
(60) Provisional application No. 63/575,148, filed on Apr. 5, 2024.

(51) Int. Cl. H01L 27/146; H01L 23/00

(52) U.S. Cl. CPC H10F 39/809; H01L 24/08; H10F 39/199; H01L 2224/08145

(57) ABSTRACT

A semiconductor device may include a plurality of single-photon avalanche diode (SPAD) pixels. The semiconductor device may be a backside device that includes a sensor wafer stacked with an integrated passive component (IPC) wafer. The sensor wafer may include the SPAD pixels in an array across the sensor wafer. The IPC wafer may include active microcells that include quench resistors and dummy microcells that omit or disconnect the quench resistors. The sensor wafer may be bonded to the IPC wafer through hybrid bonding. The regions with active microcells may form active areas of the semiconductor device, while the regions with dummy microcells may form inactive areas. In this way, the active areas and inactive areas of the semiconductor device may be configurable by adjusting the active and dummy microcells of the IPC wafer.

This application claims the benefit of U.S. provisional patent application No. 63/575,148, filed Apr. 5, 2024, which is hereby incorporated by reference herein in its entirety.

### BACKGROUND

This relates generally to imaging systems and, more particularly, to imaging systems that include single-photon avalanche diodes (SPADs) for single photon detection.

Modern electronic devices such as cellular telephones, cameras, and computers often use digital image sensors. Image sensors (sometimes referred to as imagers) may be formed from a two-dimensional array of image sensing pixels. Each pixel may include a photosensitive element (such as a photodiode) that receives incident photons (light) and converts the photons into electrical signals. Each pixel may also include a microlens that overlaps and focuses light onto the photosensitive element.

Conventional image sensors with backside-illuminated pixels may suffer from limited functionality in a variety of ways. For example, some conventional image sensors may not be able to determine the distance from the image sensor to the objects that are being imaged. Conventional image sensors may also have lower than desired image quality and resolution. To improve sensitivity to incident light, single-photon avalanche diodes (SPADs) may sometimes be used in imaging systems. However, SPADs may generate noise in response to non-target ambient light. It is within this context that the embodiments herein arise.

### BRIEF DESCRIPTION OF THE DRAWINGS

FIG. 1 is a circuit diagram showing an illustrative single-photon avalanche diode pixel in accordance with some embodiments.

FIG. 2 is a diagram of an illustrative silicon photomultiplier (SiPM) in accordance with some embodiments.

FIG. 3 is a schematic diagram of an illustrative imaging system with a SPAD-based semiconductor device in accordance with some embodiments.

FIG. 4 is a diagram of an illustrative pixel array and associated readout circuitry for reading out image signals in a SPAD-based semiconductor device in accordance with some embodiments.

FIG. 5 is side view of an illustrative SiPM formed from a sensor wafer stacked with an integrated passive component (IPC) wafer in accordance with some embodiments.

FIGS. 6A-6C are top views of illustrative SiPMs with different active area and inactive area shapes and bonding in accordance with some embodiments.

FIG. 7 includes top views of an illustrative sensor wafer, IPC wafer, and SiPM with active and inactive areas in accordance with some embodiments.

FIGS. 8A-8C are top views of illustrative IPC wafers having different bonding between active microcells and dummy microcells in accordance with some embodiments.

FIG. 9 is a top view of an illustrative SiPM with active and multiple inactive areas in accordance with some embodiments.

### DETAILED DESCRIPTION

Embodiments of the present technology relate to systems that include single-photon avalanche diodes (SPADs).

Some imaging systems include image sensors that sense light by converting impinging photons into electrons or holes that are integrated (collected) in pixel photodiodes within the sensor array. After completion of an integration cycle, collected charge is converted into a voltage, which is supplied to the output terminals of the sensor. In complementary metal-oxide semiconductor (CMOS) image sensors, the charge to voltage conversion is accomplished directly in the pixels themselves and the analog pixel voltage is transferred to the output terminals through various pixel addressing and scanning schemes. The analog pixel voltage can also be later converted on-chip to a digital equivalent and processed in various ways in the digital domain.

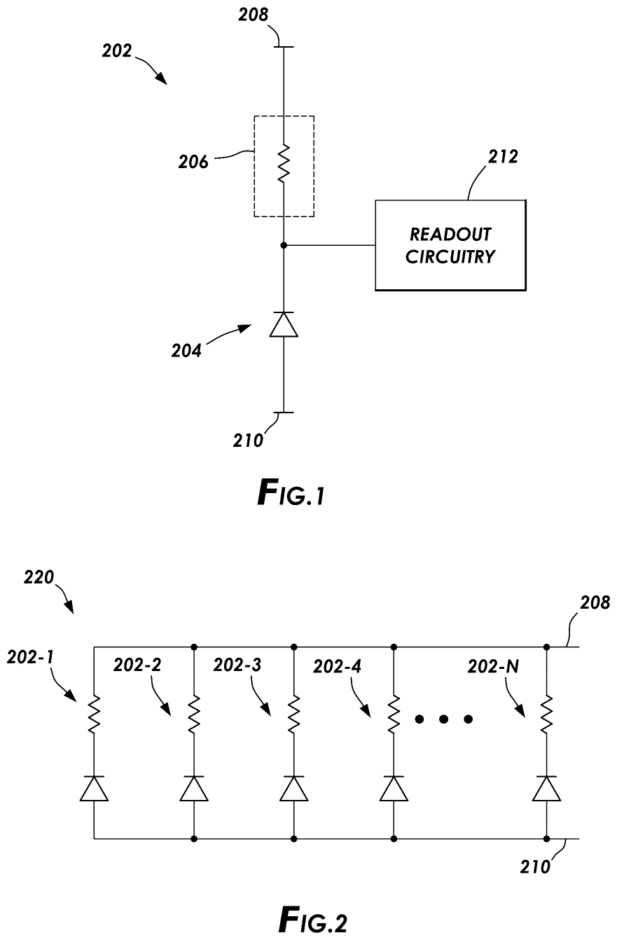

In single-photon avalanche diode (SPAD) devices (such as the ones described in connection with FIGS. 1-4), on the other hand, the photon detection principle is different. The light sensing diode is biased slightly above its breakdown point and when an incident photon generates an electron or hole, this carrier initiates an avalanche breakdown process with additional carriers being generated. The avalanche multiplication may produce a current signal that can be detected by readout circuitry associated with the SPAD.

FIG. 1 is a circuit diagram of an illustrative SPAD device 202. As shown in FIG. 1, SPAD device 202 (also referred to as SPAD pixel 202 herein) includes a SPAD 204 that is coupled in series with quenching circuitry 206 between a first supply voltage terminal 208, which may be a ground power supply voltage terminal, and a second supply voltage terminal 210, which may be a negative power supply voltage terminal. During operation of SPAD device 202, supply voltage terminals 208 and 210 may be used to reverse bias SPAD 204 to a voltage that is above the breakdown voltage. Breakdown voltage is the largest reverse voltage that can be applied without causing an exponential increase in the leakage current in the diode. When SPAD 204 is biased above the breakdown voltage in this manner, absorption of a single-photon can trigger an avalanche process generating a short-duration but relatively large avalanche current through impact ionization.

Quenching circuitry 206 (sometimes referred to as quench element 206 herein) may be used to lower the bias voltage of SPAD 204 below the level of the breakdown voltage. Lowering the bias voltage of SPAD 204 below the breakdown voltage stops the avalanche process and corresponding avalanche current. There are numerous ways to form quenching circuitry 206. Quenching circuitry 206 may be passive quenching circuitry or active quenching circuitry. Passive quenching circuitry may, without external control or monitoring, automatically quench the avalanche current once initiated. For example, FIG. 1 shows an example where a resistor (sometimes referred to as a quench resistor herein) is used to form quenching circuitry 206, which is shown as passive quenching circuitry. After the avalanche is initiated, the resulting current rapidly discharges the capacity of the device, lowering the voltage at the SPAD to near to the breakdown voltage. The resistance associated with the resistor in quenching circuitry 206 may result in the final current being lower than required to sustain itself. The SPAD may then be reset to above the breakdown voltage to enable detection of another photon.

The example of passive quenching circuitry is merely illustrative. Active quenching circuitry may also be used in SPAD device 202. Active quenching circuitry may reduce the time it takes for SPAD device 202 to be reset. This may allow SPAD device 202 to detect incident light at a faster rate than when passive quenching circuitry is used, improving the dynamic range of the SPAD device. Active quenching circuitry may modulate the SPAD quench resistance. For example, before a photon is detected, quench resistance is set high and then once a photon is detected and the avalanche is quenched, quench resistance is minimized to reduce recovery time.

SPAD device 202 may also include readout circuitry 212. There are numerous ways to form readout circuitry 212 to obtain information from SPAD device 202. Readout circuitry 212 may include a pulse counting circuit that counts arriving photons. Alternatively or additionally, readout circuitry 212 may include time-of-flight circuitry that is used to measure photon time-of-flight (ToF). The photon time-of-flight information may be used to perform depth sensing using Time-to-Digital Converter (TDC) and histogram circuitry, as an example.

In one example, photons may be counted by an analog counter to form the light intensity signal as a corresponding pixel voltage. The ToF signal may be obtained by also converting the time of photon flight to a voltage. The example of an analog pulse counting circuit being included in readout circuitry 212 is merely illustrative. If desired, readout circuitry 212 may include digital pulse counting circuits. Readout circuitry 212 may also include amplification circuitry, if desired.

The example in FIG. 1 of readout circuitry 212 being coupled to a node between SPAD 204 and quenching circuitry 206 is merely illustrative. Readout circuitry 212 may be coupled to any desired portion of the SPAD device. In some cases, quenching circuitry 206 may be considered integral with readout circuitry 212.

Because SPAD devices can detect a single incident photon, the SPAD devices are effective at imaging scenes with low light levels. Each SPAD may detect how many photons are received within a given period of time, such as by using readout circuitry that includes a counting circuit. However, as discussed above, each time a photon is received and an avalanche current initiated, the SPAD device must be quenched and reset before being ready to detect another photon. As incident light levels increase, the reset time becomes limiting to the dynamic range of the SPAD device. In particular, once incident light levels exceed a given level, the SPAD device is triggered immediately upon being reset.

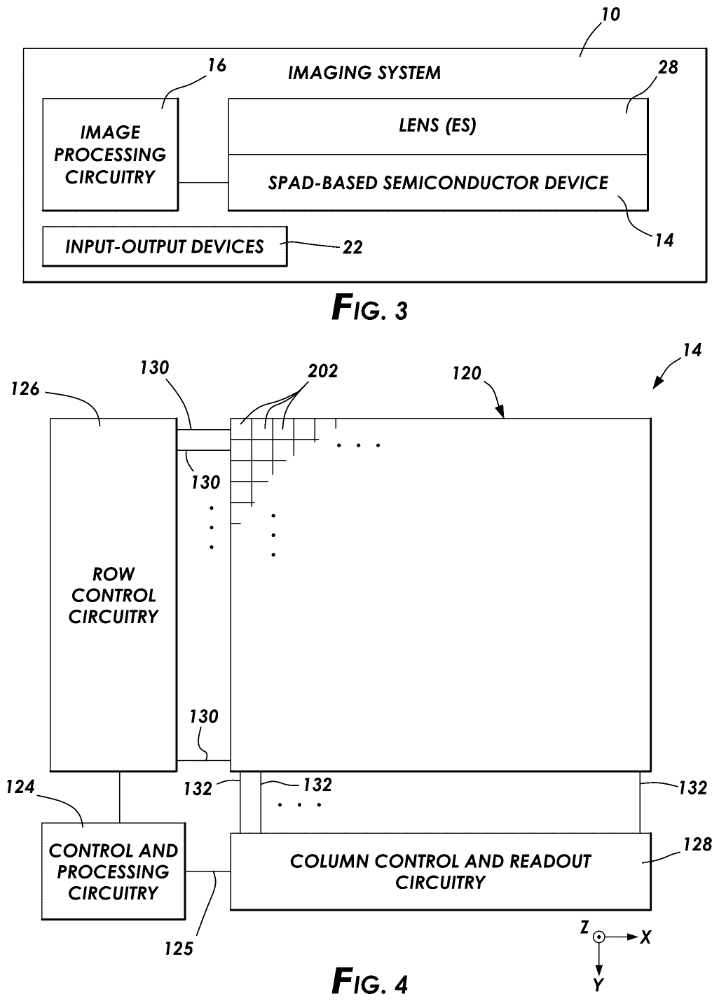

Multiple SPAD devices may be grouped together to increase dynamic range. FIG. 2 is a circuit diagram of an illustrative group 220 of SPAD devices 202. The group of SPAD devices may be referred to as silicon photomultiplier (SiPM) 220. As shown in FIG. 2, silicon photomultiplier 220 may include multiple SPAD devices that are coupled in parallel between first supply voltage terminal 208 and second supply voltage terminal 210. FIG. 2 shows N SPAD devices 202 coupled in parallel. In particular, silicon photomultiplier 220 may include SPAD device 202-1, SPAD device 202-2, SPAD device 202-3, SPAD device 202-4, . . . , SPAD device 202-N. More than two SPAD devices, more than ten SPAD devices, more than one hundred SPAD devices, or more than one thousand SPAD devices may be included in a given silicon photomultiplier.

Herein, each SPAD device 202 may be referred to as a SPAD pixel 202. Although not shown explicitly in FIG. 2, readout circuitry for the silicon photomultiplier may measure the combined output current from all of SPAD pixels in the silicon photomultiplier. In this way, the dynamic range of an imaging system including the SPAD pixels may be increased. Each SPAD pixel is not guaranteed to have an avalanche current triggered when an incident photon is received, but each SPAD pixel may have an associated probability of an avalanche current being triggered when an incident photon is received. There is a first probability of an electron being created when a photon reaches the diode and then a second probability of the electron triggering an avalanche current. The total probability of a photon triggering an avalanche current may be referred to as the SPAD's photon-detection efficiency (PDE). Grouping multiple SPAD pixels together in the silicon photomultiplier therefore allows for a more accurate measurement of the incoming incident light, counting the number of incident photons.

The example of a plurality of SPAD pixels having a common output in a silicon photomultiplier is merely illustrative. In the case of an imaging system including a silicon photomultiplier having a common output for all of the SPAD pixels, the imaging system may not have any resolution in imaging a scene and the silicon photomultiplier may detect photon flux at a single point. It may be desirable to use SPAD pixels to obtain image data across an array to allow a higher resolution reproduction of the imaged scene. In cases such as these, SPAD pixels in a single imaging system may have per-pixel readout capabilities. Alternatively, an array of silicon photomultipliers, each including more than one SPAD pixel, may be included in the imaging system. The outputs from each pixel or from each silicon photomultiplier may be used to generate image data for an imaged scene. The array may be capable of independent detection, whether using a single SPAD pixel or a plurality of SPAD pixels in a silicon photomultiplier, in a line array. The line array may have a single row and multiple columns, may have a single column and multiple rows, or may have more than ten, more than one hundred, or more than one thousand rows and/or columns.

While there are a number of possible use cases for SPAD pixels as discussed above, the underlying technology used to detect incident light is the same. All of the aforementioned examples of devices that use SPAD pixels may collectively be referred to as SPAD-based semiconductor devices (also referred to as semiconductor devices herein). A silicon photomultiplier with a plurality of SPAD pixels having a common output may be referred to as a SPAD-based semiconductor device or a semiconductor device. An array of SPAD pixels with per-pixel readout capabilities may be referred to as a SPAD-based semiconductor device or a semiconductor device. An array of silicon photomultipliers with per-silicon-photomultiplier readout capabilities may be referred to as a SPAD-based semiconductor device or a semiconductor device.

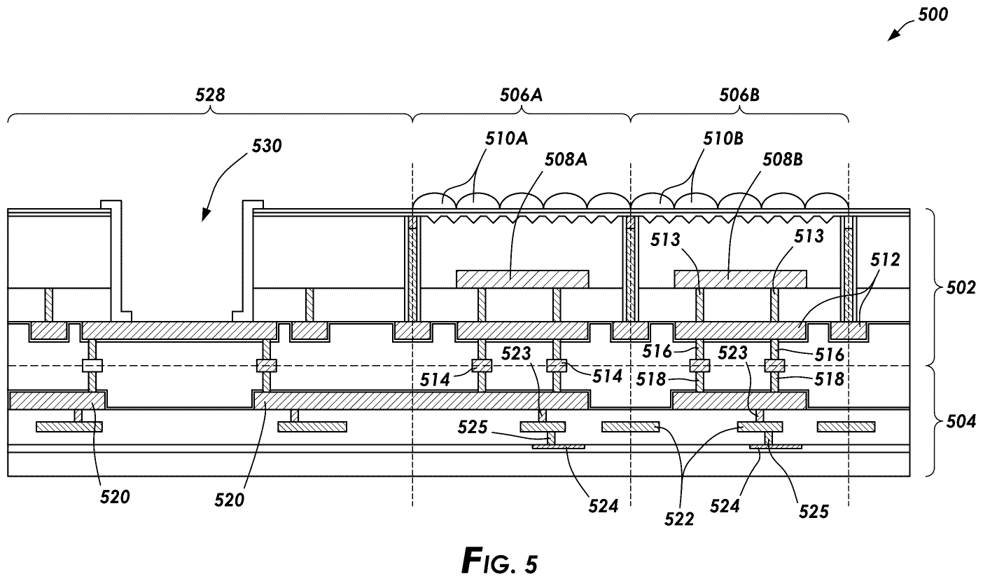

An imaging system 10 with a SPAD-based semiconductor device is shown in FIG. 3. Imaging system 10 may be an electronic device such as a digital camera, a computer, a cellular telephone, a medical device, or other electronic device. Imaging system 10 may be an imaging system on a vehicle (sometimes referred to as vehicular imaging system). Imaging system 10 may be used for LIDAR applications.

Imaging system 10 may include one or more SPAD-based semiconductor devices 14 (sometimes referred to as semiconductor devices 14, devices 14, SPAD-based image sensors 14, or image sensors 14). One or more lenses 28 may optionally cover each semiconductor device 14. During operation, lenses 28 (sometimes referred to as optics 28) may focus light onto SPAD-based semiconductor device 14. SPAD-based semiconductor device 14 may include SPAD pixels that convert the light into digital data. The SPAD-based semiconductor device may have any number of SPAD pixels, such as hundreds, thousands, or millions of SPAD pixels.

The SPAD-based semiconductor device 14 may optionally include additional circuitry such as bias circuitry, such as source follower load circuits, sample and hold circuitry, amplifier circuitry, analog-to-digital (ADC), time-to-digital (TDC) converter circuitry, data output circuitry, memory, such as buffer circuitry, address circuitry, and/or other suitable circuitry.

Image data from semiconductor device 14 may be provided to image processing circuitry 16. Image processing circuitry 16 may be used to perform image processing functions such as automatic focusing functions, depth sensing, data formatting, adjusting white balance and exposure, implementing video image stabilization, face detection, and/or other suitable functions. For example, during automatic focusing operations, image processing circuitry 16 may process data gathered by SPAD pixels 202 to determine the magnitude and direction of lens movement, such as the movement of lens(es) 28, needed to bring an object of interest into focus. Image processing circuitry 16 may process data gathered by the SPAD pixels to determine a depth map of the scene.

Imaging system 10 may provide a user with numerous high-level functions. In a computer or advanced cellular telephone, for example, a user may be provided with the ability to run user applications. To implement these functions, the imaging system may include input-output devices 22, such as keypads, buttons, input-output ports, joysticks, and displays. Additional storage and processing circuitry such as volatile and nonvolatile memory, which may include random-access memory, flash memory, hard drives, and/or solid state drives; microprocessors; microcontrollers; digital signal processors; application specific integrated circuits; and/or other processing circuits may also be included in the imaging system.

Input-output devices 22 may include output devices that work in combination with the SPAD-based semiconductor device. For example, a light-emitting component may be included in the imaging system to emit light, such as infrared light or light of any other desired wavelength. Semiconductor device 14 may measure the reflection of the light from an object to measure distance to the object in a LIDAR (light detection and ranging) scheme.

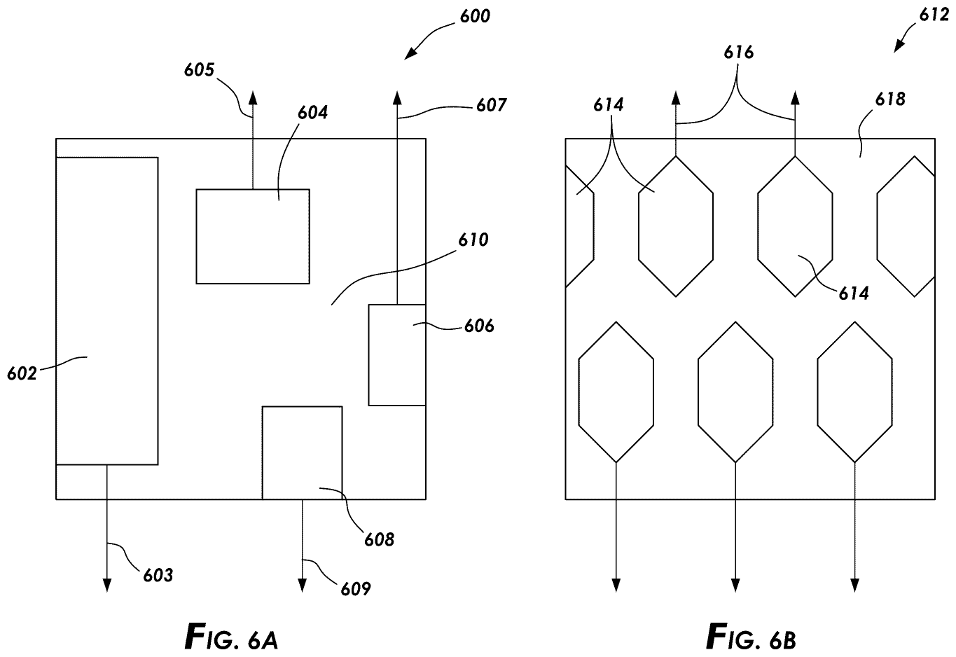

FIG. 4 shows one example for a semiconductor device 14 that includes an array 120 of SPAD pixels 202 (sometimes referred to herein as image pixels or pixels) arranged in rows and columns. Array 120 may contain, for example, hundreds or thousands of rows and columns of SPAD pixels 202. Each SPAD pixel 202 may be coupled to an analog pulse counter that generates a corresponding pixel voltage based on received photons or a digital pulse counter whose digital output code corresponds to the number of photons in a defined time window. Each SPAD pixel may additionally or alternatively be coupled to a time-of-flight to voltage converter circuit. In both types of readout circuits, voltages may be stored on pixel capacitors and may later be scanned in a row-by-row fashion. Control circuitry 124 may be coupled to row control circuitry 126 and image readout circuitry 128 (sometimes referred to as column control circuitry, readout circuitry, processing circuitry, or column decoder circuitry). Row control circuitry 126 may receive row addresses from control circuitry 124 and supply corresponding row control signals to SPAD pixels 202 over row control paths 130. One or more conductive lines such as column lines 132 may be coupled to each column of pixels 202 in array 120. Column lines 132 may be used for reading out image signals from pixels 202 and for supplying bias signals, such as bias currents or bias voltages, to pixels 202. If desired, during pixel readout operations, a pixel row in array 120 may be selected using row control circuitry 126 and image signals generated by SPAD pixels 202 in that pixel row can be read out along column lines 132.

Image readout circuitry 128 may receive image signals, such as analog or digital signals from the SPAD pixels, over column lines 132. Image readout circuitry 128 may include sample-and-hold circuitry for sampling and temporarily storing image signals read out from array 120, amplifier circuitry, analog-to-digital conversion (ADC) or time-to-digital conversion (TDC) circuitry, bias circuitry, column memory, latch circuitry for selectively enabling or disabling the column circuitry, or other circuitry that is coupled to one or more columns of pixels in array 120 for operating pixels 202 and for reading out signals from pixels 202. ADC circuitry in readout circuitry 128 may convert analog pixel values received from array 120 into corresponding digital pixel values (sometimes referred to as digital image data or digital pixel data). Instead, TDC circuity in readout circuitry 128 may convert the photon arrival times from array 120 into corresponding digital values to form a depth map. Alternatively, ADC or TDC circuitry may be incorporated into each SPAD pixel 202. Image readout circuitry 128 may supply digital pixel data to control and processing circuitry 124 and/or image processing and data formatting circuitry 16 (FIG. 1) over path 125 for pixels in one or more pixel columns.

The example of semiconductor device 14 having readout circuitry to read out signals from the SPAD pixels in a row-by-row manner is merely illustrative. In other embodiments, the readout circuitry in the image sensor may simply include digital pulse counting circuits coupled to each SPAD pixel. Any other desired readout circuitry arrangement may be used.

If desired, array 120 may be part of a stacked-die arrangement in which pixels 202 of array 120 are split between two or more stacked substrates. Alternatively, pixels 202 may be formed in a first substrate and some or all of the corresponding control and readout circuitry may be formed in a second substrate. Each of the pixels 202 in the array 120 may be split between the two dies at any desired node within pixel.

It should be understood that instead of having an array of SPAD pixels as in FIG. 4, SPAD-based semiconductor device 14 may instead have an array of silicon photomultipliers (each of which includes multiple SPAD pixels with a common output), such as is shown in FIG. 2. Moreover, although FIG. 3 shows an imaging system with semiconductor device 14, semiconductor device 14 may be a standalone device, such as the SiPM of FIG. 2.

Regardless of the layout of semiconductor device 14, the SPADs in an SiPM may detect both target light (e.g., light emitted by a light emitting component and reflected to the SPADs) and ambient illumination as background noise. The presence of the ambient light illumination may decrease the signal-to-noise ratio (SNR) of the SiPM. To improve the SNR of an SiPM, the SiPM may be modified to have an active area that matches the expected pattern of received target light (e.g., based on the light source type, the wavelength emitted, the optics between the light source and the SiPM, and/or any other suitable characteristic(s)). In this way, the SiPM may detect less ambient illumination, and the SNR of the SiPM may be improved.

To accommodate SiPMs with different active area sizes and patterns, the SiPMs may be formed from two wafer layers—a sensor wafer and an integrated passive component (IPC) wafer. The sensor wafer may have an array of pixels (SPAD pixels) that extends across the wafer. The IPC wafer may have metal layers and quench resistors. In particular, in the active areas of the SiPM, the IPC wafer may have quench resistors, allowing the SPAD pixels to reset and detect light. In inactive areas (dummy areas), the IPC wafer may not have quench resistors, or may have quench resistors uncoupled from the overlying SPAD pixels. In this way, the IPC wafer may define the active and inactive areas of the SiPM. An illustrative side view of an SiPM formed from stacked wafers is shown in FIG. 5.

As shown in FIG. 5, SiPM 500 may be a backside illuminated (BSI) semiconductor device that includes sensor wafer 502 and IPC wafer 504. Sensor wafer 502 and IPC wafer 504 may be formed from silicon or other suitable semiconductor material.

Sensor wafer 502 may include SPADs 508A and 508B. SPADs 508A and 508B may be overlapped by microlenses 510A and 510B, respectively. Each SPAD 508 may form a microcell within SiPM 500, as shown by microcells 506A and 506B. Microlenses 510A and 510B may be formed from glass, polymer or other suitable material, and may overlap each SPAD in each microcell to redirect light incident on each microcell on to the respective SPAD junction. SPADs 508 may be coupled to top metal layer 512 through vias 513.

IPC wafer 504 may include metal layers 520 and 522, as well as quench resistors 524. Quench resistors 524 may be coupled to metal layer 522 through vias 525, and metal layer 522 may in turn be coupled to metal layer 520 through vias 523.

Sensor wafer 502 may be coupled to IPC wafer 504 using hybrid bonding. In particular, hybrid bonds 514 may couple sensor wafer 502 to IPC wafer 504. Hybrid bonds 514 may be formed from copper or other suitable material, such as another metal material. Hybrid bonds 514 may be coupled to metal layer 512 through vias 516 and to metal layer 520 through vias 518. Additionally, hybrid bonds 514 may be coupled to the semiconductor material that forms sensor wafer 502 and IPC wafer 504. For example, thermal processing may be used to couple hybrid bonds 514 to wafers 502 and 504.

SiPM 500 may also include bond pad region 528. Bond pad region 528 may include through-silicon via (TSV) etching 530 in sensor wafer 502. Bond pad region 528 may also include metal layers 512, 520, and 522, as well as vias 516, 518, 523, and 525, which may couple microcells (e.g., microcells 506A and 506B) in SiPM 500 to one another and/or to readout circuitry. Bond pad region 528 may omit quench resistors (e.g., quench resistors 524) in IPC wafer 504.

However, the example of bond pad region 528 in FIG. 5 is merely illustrative. In some embodiments, for example, bond pad regions in SiPM 500 may include different metal layers from the microcells in SiPM 500.

Although wafer 504 has been described as including passive quenching circuitry (that includes passive quench resistors 524), this is merely illustrative. In some embodiments, wafer 504 may include active quenching circuitry. Therefore wafer 504 may sometimes be referred to as an integrated component wafer, which may include passive and/or active components.

In operation, SPADs 508 may be triggered by photons incident on SiPM 500. When SPADs 508 are triggered, a corresponding signal may be sent through metal layers 512, 520, and/or 522 to an output, such as an output cathode in SiPM 500. After SPADs 508 are triggered, they may be reset passively using quench resistors 524. In this way, SiPM 500 may detect light using SPADs 508 in sensor wafer 502, and SPADs 508 may be reset using quench resistors 524 in IPC wafer 504.

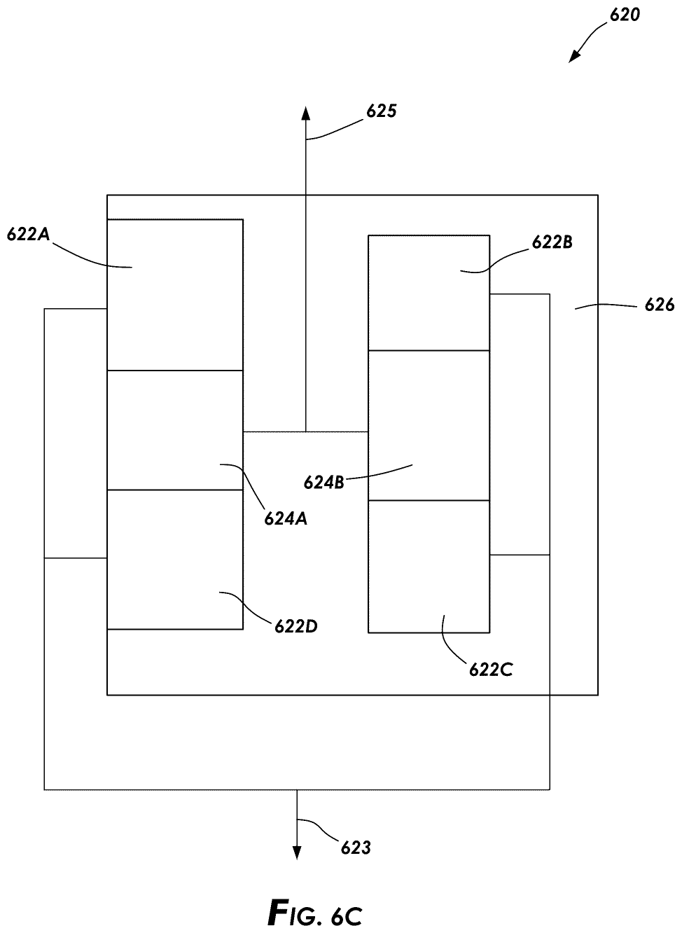

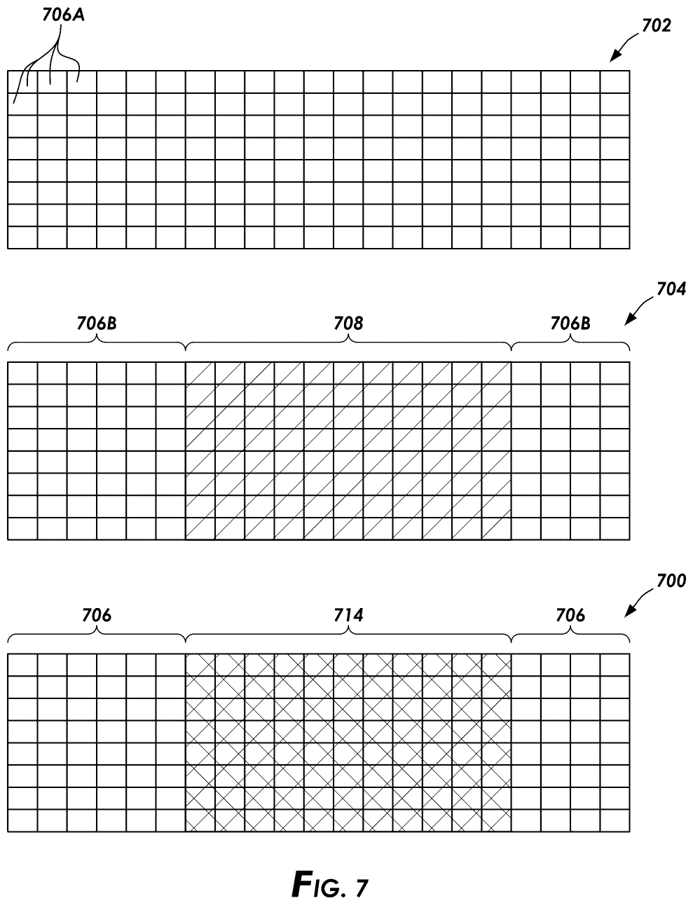

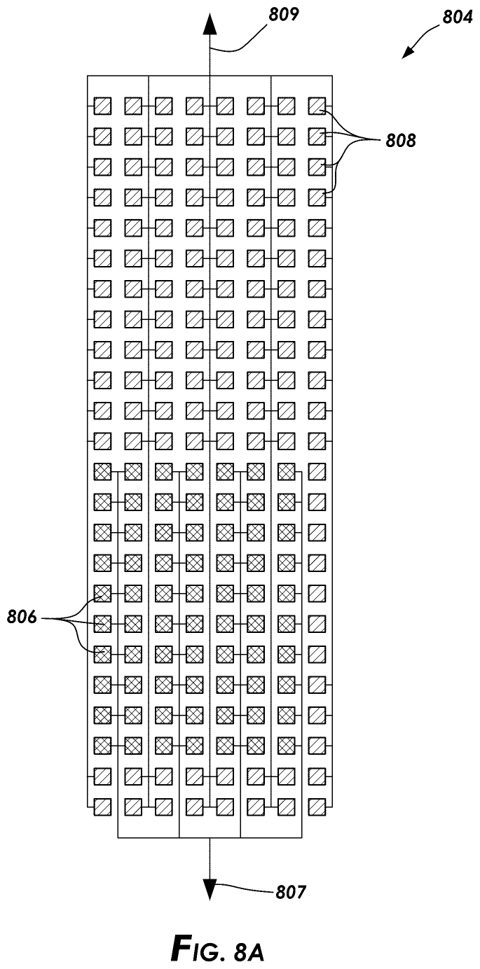

By forming an SiPM, such as SiPM 500, from stacked wafers, the active area (e.g., the area in which SPADs detect incident light) may be adjusted by adjusting one or both wafers. In some illustrative embodiments, for example, sensor wafer 502 may include SPADs that extend across a surface of sensor wafer 502 (e.g., in an array), while IPC wafer 504 may have some dummy regions that are modified to form inactive areas. For example, the dummy regions may omit passive quench resistors 524, one or more of metal layers 520 and/or 522, and/or one or more of vias 518, 523, and/or 525. By forming dummy regions in IPC wafer 504, inactive regions may be formed in SiPM 500. Illustrative examples of SiPMs having active and inactive areas are shown in FIGS. 6A-6B.

As shown in FIG. 6A, SiPM 600, which may correspond with SiPM 500 of FIG. 5, may have active areas 602, 604, 606, and 608. For example, active areas 602, 604, 606, and 608 may be formed using a sensor wafer (e.g., sensor wafer 502 of FIG. 5) stacked on an IPC wafer (e.g., IPC wafer 504 of FIG. 5) with quench resistors in the regions of active areas 602, 604, 606, and 608. Inactive area 610 may be formed between active areas 602, 604, 606, and 608, and may be formed by omitting and/or disconnecting quench resistors in the IPC wafer within inactive area 610.

Active areas 602, 604, 606, and 608 may each include multiple microcells (e.g., microcells 506 of FIG. 5), each with a respective SPAD. For example, active areas 602, 604, 606, and 608 (also referred to as active area pixels herein) may each be formed from at least 10 microcells, at least 20 microcells, at least 40 microcells, at least 50 microcells, at least 100 microcells, or at least 125 microcells, as examples. Alternatively, active areas 602, 604, 606, and/or 608 may be formed from a single microcell with a SPAD. Active areas 602, 604, 606, and 608 may each have individual outputs over lines 603, 605, 607, and 609, respectively.

Although FIG. 6A shows active areas 602, 604, 606, and 608 with rectangular shapes and individual outputs for each active area, this is merely illustrative. In general, active areas in an SiPM may have any suitable shape in terms of microcells, and multiple active areas may have a shared output, if desired.

For example, as shown in the illustrative example of FIG. 6B, SiPM 612, which may correspond to SiPM 500 of FIG. 5, may have hexagonal active areas 614 with individual output lines 616. Hexagonal active areas 614 may be separated by inactive area 618.

Hexagonal active areas 614 may be formed using a sensor wafer (e.g., sensor wafer 502 of FIG. 5) stacked on an IPC wafer (e.g., IPC wafer 504 of FIG. 5) with quench resistors in the regions of active areas 614. Inactive area 618 may be formed between active areas 614, and may be formed by omitting and/or disconnecting quench resistors in the IPC wafer within inactive area 618.

Hexagonal active areas 614 may each include multiple microcells (e.g., microcells 506 of FIG. 5), each with a respective SPAD. Alternatively, hexagonal active areas 614 may be formed from a single microcell with a SPAD. Hexagonal active areas 614 may each have a dedicated output over lines 616, as shown in FIG. 6B, or multiple hexagonal active areas 614 may be output over shared lines.

Although FIGS. 6A and 6B show active areas that are separated by one or more inactive areas, this is merely illustrative. In some embodiments, active areas may abut one another (e.g., an edge of one active area may be adjacent to an edge of another active area). The abutting active areas may be rectangular, square, hexagonal, circular, octagonal, or have any other suitable shape(s) defined by the microcell size.

An illustrative example of an SiPM that has output lines shared between multiple active areas, as well as adjacent active areas, is shown in FIG. 6C.

As shown in FIG. 6C, SiPM 620, which may correspond with SiPM 500 of FIG. 5, may have active areas 622A, 622B, 622C, 622D, 624A, and 624B. For example, active areas 622A, 622B, 622C, 622D, 624A, and 624B may be formed using a sensor wafer (e.g., sensor wafer 502 of FIG. 5) stacked on an IPC wafer (e.g., IPC wafer 504 of FIG. 5) with quench resistors in the regions of active areas 622A, 622B, 622C, 622D, 624A, and 624B. Inactive area 626 may be formed between active areas 622A, 622B, 622C, 622D, 624A, and 624B, and may be formed by omitting and/or disconnecting quench resistors in the IPC wafer within inactive area 626.

Active areas 622A, 622B, 622C, 622D, 624A, and 624B may each include multiple microcells (e.g., microcells 506 of FIG. 5), each with a respective SPAD. Alternatively, active areas 622A, 622B, 622C, 622D, 624A, and/or 624B may each be formed from a single microcell with a SPAD. Active areas 622A, 622B, 622C, 622D may be output over shared output line 623, while active areas 624A and 624B may be output over shared output line 625. In this way, the outputs of multiple active areas may be combined over shared output lines.

The illustrative examples of the active area shapes and output lines in FIGS. 6A-C are merely illustrative. In general, an SiPM may have any suitable number of active area(s), each of which with any desired shape, and one or more active areas may be output over a given output line. Additionally, although the examples of FIGS. 6A-6C each show a single inactive area, this is merely illustrative. In general, an SiPM may have any suitable number of active areas and inactive areas.

As discussed, a sensor wafer (e.g., sensor wafer 502 of FIG. 5) and an IPC wafer (e.g., IPC wafer 504 of FIG. 5) may form an SiPM with one or more active areas by varying the active microcells within the IPC wafer. An illustrative example is shown in FIG. 7.

As shown in FIG. 7, sensor wafer 702 (which may correspond with sensor wafer 502 of FIG. 5) may have microcells 706A that extend across an entirety of sensor wafer 702 (e.g., entirely between side edges of the sensor wafer and entirely between a top and bottom edge of the sensor wafer). For example, sensor wafer 702 may include at least 100 microcells, at least 500 microcells, at least 1000 microcells, at least 1250 microcells, or at least 1400 microcells, as examples. Microcells 706A may be arranged in an array, as shown in FIG. 7, or may be arranged in another suitable pattern. Each microcell 706A may include a SPAD and associated metal layers (e.g., as shown in FIG. 5).

IPC wafer 704 (which may correspond with IPC wafer 504 of FIG. 5) may have active microcells 706B in some regions, and dummy microcells 708 in other regions. Active microcells 706B may have quench resistors (e.g., quench resistors 524 of FIG. 5) coupled to metal layers in IPC wafer 704, while dummy microcells 708 may omit quench resistors or have quench resistors that are disconnected from the other metal layers (e.g., the quench resistors may be floating) in IPC wafer 704. IPC wafer 704 may include at least 25 active microcells, at least 100 active microcells, at least 250 active microcells, at least 500 active microcells, at least 750, or at least 1500 active microcells, as examples. In embodiments in which IPC wafer 704 has more active microcells than sensor wafer 702 has microcells, multiple sensor wafers 702 may be bonded to IPC wafer 704.

In the example of FIG. 7, dummy microcells 708 may be between active microcells 706B. However, this arrangement is merely illustrative. In general, active microcells 706B may be formed in any suitable shapes and/or patterns (e.g., as shown in FIGS. 6A-6C), and dummy microcells 708 may be formed in any suitable position(s) relative to active microcells 706B. For example, in some embodiments, dummy microcells 708 may surround each active area defined by active microcells 706B.

SiPM 700 may be formed by stacking sensor wafer 702 and IPC wafer 704 and attaching sensor wafer 702 to IPC wafer 704 using hybrid bonding. The resulting SiPM 700 may have microcells 706 that define active areas (e.g., due to the presence of active microcells 706B in those regions) and inactive area 714 (e.g., due to the presence of dummy microcells 708 in that region). In this way, by varying the locations of dummy microcells 708 in IPC wafer 704, the size, shapes, and locations of the active areas defined by microcells 706 may be adjusted. In other words, IPC wafer 704 may be configured with different locations and/or patterns of dummy microcells 708 and active microcells 706B to in turn configure the locations and/or patterns of the active and inactive areas of SiPM 700.

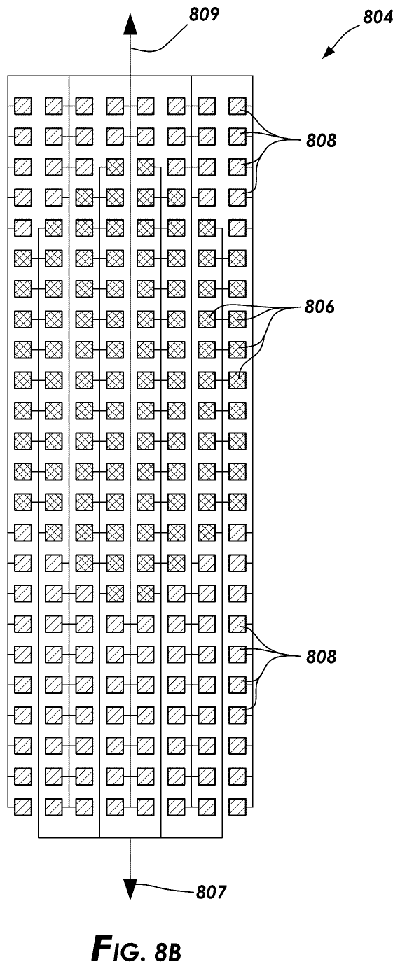

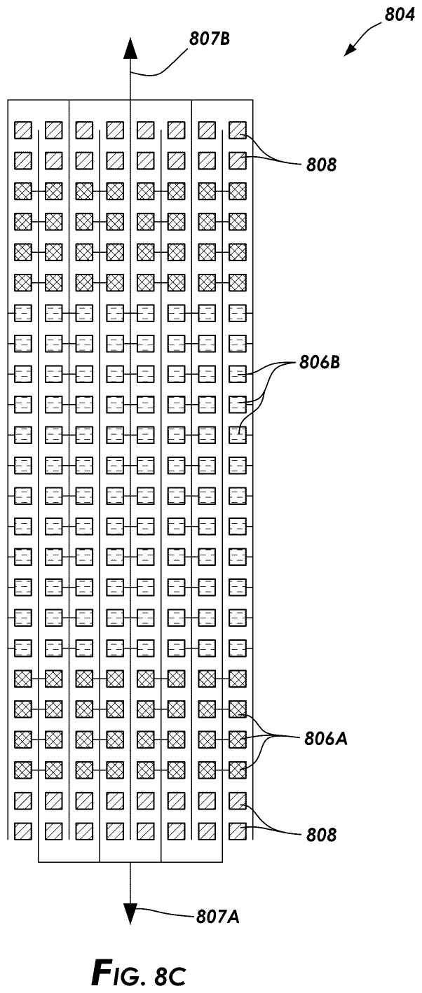

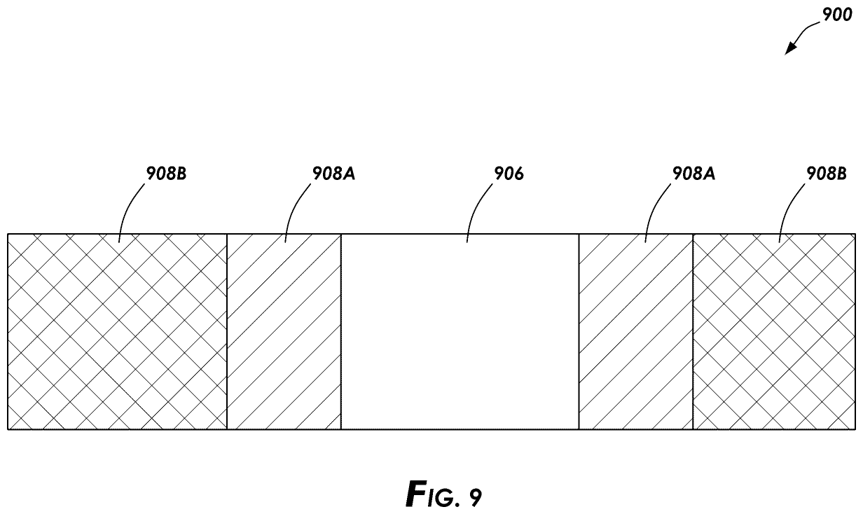

In general, dummy microcells in an IPC wafer, such as dummy microcells 708 of FIG. 7, may be coupled to a common anode to ensure proper definition and functionality of the surrounding active areas (e.g., by ensuring that the dummy microcells are not floating). Illustrative examples are shown in FIGS. 8A-8C.

As shown in FIGS. 8A-8C, IPC wafer 804, which may correspond with IPC wafers 504 and 704 of FIGS. 5 and 7, may include active microcells 806 (which may correspond to active microcells 706B of FIG. 7) and dummy microcells 808 (which may correspond to dummy microcells 708 of FIG. 7). Active microcells 806 may be coupled to common output line 807, which may in turn be coupled to an output cathode. Signals generated by active microcells 806 (e.g., by the SPADs coupled to active microcells 806) may be read out over output line 807.

As shown in FIG. 8A, dummy microcells 808 may be coupled to common line 809, which in turn may be coupled to a common anode. In this way, dummy microcells 808 may be shorted to a common anode (not floating).

Dummy microcells 808 may be shorted to a common anode regardless of the location(s) of dummy microcells 808 relative to active microcells 806. As shown in illustrative FIG. 8B, for example, dummy microcells 808 on either side of active microcells 806 may be shorted to a common anode through common line 809. Dummy microcells 808 may be coupled to common line 809 with lines that run between active microcells 806 and/or lines that run around a perimeter of active microcells 806.

In some embodiments, dummy microcells 808 may be coupled to a common anode using hybrid bonding. In particular, dummy microcells 808 in an IPC wafer may be coupled via hybrid bonding to the metal layers in an overlying sensor wafer (e.g., sensor wafer 502 of FIG. 5). Through these metal layers, dummy microcells 808 may be coupled to the common anode. For example, in the illustrative FIG. 8C, active microcells 806A may be coupled to a first output cathode over output line 807A and active microcells 806B may be coupled to a second output cathode over output line 807B. Dummy microcells 808 may be coupled to the common anode through hybrid bonding (e.g., through hybrid bonds 514 of FIG. 5). In this way, all of dummy microcells 808 may be biased using the common anode.

Although FIGS. 7-8 show active area pixels formed from active microcells 708/808 adjacent to one another, this is merely illustrative. In some embodiments, inactive microcells 708/808 may be formed between at least some of active microcells 706/806. In this way, active area pixels may be defined by active microcells 706/806, and inactive microcells 708/808 may form gaps between the active area pixels. For example, inactive microcells 708/808 may form gaps of at least 1 microcell pitch (e.g., microcell size), at least 2 microcell pitches, at least 5 microcell pitches, at least 10 microcell pitches, at least 20 microcell pitches, at least 40 microcell pitches, or at least 60 microcell pitches, as examples, between active area pixels defined by active microcells 706/806.

Dummy microcells 808 have been described as being coupled to a common anode through output lines 807. Additionally or alternatively, some of dummy microcells 808 may be coupled to a different node. An illustrative example is shown in FIG. 9.

As shown in FIG. 9, SiPM 900, which may correspond to SiPM 500 of FIG. 5, may include active area 906, which may include active IPC wafer microcells, and inactive areas 908A and 908B, which may include dummy IPC wafer microcells.

The dummy IPC wafer microcells in inactive areas 908A may be coupled to a common anode. In particular, because inactive areas 908A are formed adjacent to active area 906 (e.g., closer to active area than inactive areas 908B), it may be desirable for inactive areas 908A to maintain uniformity with active area 906. Therefore, the dummy IPC wafer microcells in inactive areas 908A may be coupled to the common anode, such as through a common line (e.g., line 809 of FIGS. 8A and 8B) or through hybrid bonding (e.g., through the metal layers of SiPM 900, as shown in FIG. 5).

In contrast, the dummy IPC microcells in inactive areas 908B may be present to ensure the proper density of metal layers within SiPM 900 and may be formed further from active area 906 rather than inactive areas 908A. Therefore, the dummy IPC microcells in inactive areas 908B may have a reduced poly resistor (e.g., a poly resistor with a reduced surface area) as compared with the dummy IPC microcells in inactive areas 908A (as well as the poly resistors in active area 906). In this way, the dummy IPC microcells in inactive areas 908B may account for density in SiPM 900.

It will be recognized by one skilled in the art that the present exemplary embodiments may be practiced without some or all of these specific details. In other instances, well-known operations have not been described in detail in order not to unnecessarily obscure the present embodiments.

The foregoing is merely illustrative and various modifications can be made to the described embodiments. The foregoing embodiments may be implemented individually or in any combination.

What is claimed is:

1. A semiconductor device comprising active areas and an inactive area, the semiconductor device comprising:
a sensor wafer comprising a plurality of microcells, wherein each of the microcells has a respective single-photon avalanche diode (SPAD) device; and
an integrated passive component (IPC) wafer coupled to the sensor wafer, wherein the IPC wafer comprises active microcells that form the active areas and dummy microcells that form the inactive area.

2. The semiconductor device of claim 1, wherein the IPC wafer is coupled to the sensor wafer via hybrid bonding.

3. The semiconductor device of claim 2, further comprising:
a common anode, wherein each of the dummy microcells is coupled to the common anode.

4. The semiconductor device of claim 3, wherein the dummy microcells are coupled to the common anode through a common line.

5. The semiconductor device of claim 3, wherein the dummy microcells are coupled to the common anode through the hybrid bonding.

6. The semiconductor device of claim 3, wherein each of the active microcells of the IPC wafer comprises a quench resistor.

7. The semiconductor device of claim 6, wherein the dummy microcells are free from quench resistors.

8. The semiconductor device of claim 6, wherein the dummy microcells comprise floating quench resistors coupled to the common anode.

9. The semiconductor device of claim 2, wherein the dummy microcells comprise a first set of dummy microcells and a second set of dummy microcells, the semiconductor device comprising:
a common anode, wherein the first set of dummy microcells and the second set of dummy microcells are coupled to the common anode and a reduced poly resistor.

10. The semiconductor device of claim 9, wherein the first set of dummy microcells are a first distance from the active microcells, and the second set of dummy microcells are a second distance from the active microcells that is greater than the first distance.

11. The semiconductor device of claim 1, wherein each of the active areas is coupled to a respective output line.

12. The semiconductor device of claim 1, wherein the at least some of the active areas are coupled to a common output line that is coupled to a common cathode.

13. The semiconductor device of claim 1, wherein the active areas are separated by the inactive area.

14. The semiconductor device of claim 1, wherein the inactive area surrounds one of the active areas.

15. A backside-illuminated silicon photomultiplier, comprising:
a sensor wafer comprising an array of single-photon avalanche diode (SPAD) devices; and
an integrated passive component (IPC) wafer bonded to the sensor wafer, wherein the IPC wafer comprises first microcells with quench resistors and second microcells without quench resistors.

16. The backside-illuminated silicon photomultiplier of claim 15, wherein the sensor wafer has a first edge and an opposing second edge, and the array of SPAD devices extends entirely from the first edge to the second edge.

17. The backside-illuminated silicon photomultiplier of claim 16, wherein the first microcells define active areas that generate signals in response to incident light and the second microcells define inactive areas.

18. The backside-illuminated silicon photomultiplier of claim 17, wherein the inactive areas separate at least some of the active areas.

19. A semiconductor device comprising configurable active areas and inactive areas, the semiconductor device comprising:
a sensor wafer comprising a plurality of microcells, wherein each of the microcells has a respective single-photon avalanche diode (SPAD) device; and
an integrated component wafer coupled to the sensor wafer, wherein the integrated component wafer comprises active microcells that form the active areas and dummy microcells that form the inactive areas, and wherein the active microcells and the dummy microcells are configurable to configure the active areas and the inactive areas.

20. The semiconductor device of claim 19, further comprising:
a common anode, wherein the dummy microcells are coupled to the common anode.
